(19) United States
(12) Patent Application Publication
(10) Pub. No.: US 2006/0054914 A1
(43) Pub. Date: Mar. 16, 2006

(54) Composite heat conductive structure for a LED package

(75) Inventor: Chang Hsian Yi, Taichung Hsien (CN)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: SEN TECH Co., Ltd.

(21) Appl. No.: 11/223,070

(22) Filed: Sep. 9, 2005

(30) Foreign Application Priority Data
Sep. 10, 2004 (CN) 093214428

(51) Int. Cl. H01L 33/00

(52) U.S. Cl. 257/100

(57) ABSTRACT

A composite heat conductive structure for a LED package includes an upper heat conductive base plate substantially made of ceramic material with a hole and a lower heat conductive member with a hollow portion of cylindrical shape on a top surface thereof. The lower heat conductive member is detachably secured to the upper heat conductive base plate by embedding the hollow portion of cylindrical shape in the hole, thereby disposing a light emitting diode on the top surface of the lower heat conductive member within the hollow portion of cylindrical shape.

### BACKGROUND OF THE INVENTION

The invention relates to the field of a heat dissipation design. More particularly, the invention relates to the field of a heat dissipation design for light emitting diode (LED).

A number of LEDs that use semiconductor light emitting elements to produce light have been proposed. For example, a white LED can be produced by arranging a semiconductor light emitting element on a substrate and encapsulating it in a transparent resin containing fluorescent material.

Presently, the packaging of surface mount devices of light-emitting diodes (SMD LED) is mainly divided into circuit type and leadframe type. However, The SMD LED has a common shortcoming, i.e. poor heat dissipation. This is due to poor thermal conductance of the packaging resins and substrates. Besides, LED itself is a small heat-generating object, so the temperature increase due to poor heat dissipation will affect emitting efficiency and quality.

### SUMMARY OF THE INVENTION

An exemplary embodiment of the invention provides a composite heat conductive structure for a LED package including an upper heat conductive base plate substantially made of ceramic material with a hole and a lower heat conductive member with a hollow portion of cylindrical shape on a top surface thereof. The lower heat conductive member is detachably secured to the upper heat conductive base plate by embedding the hollow portion of cylindrical shape in the hole, thereby disposing a light emitting diode on the top surface of the lower heat conductive member within the hollow portion of cylindrical shape.

Another exemplary embodiment of the invention provides a LED package including an upper heat conductive base plate substantially made of ceramic material. An insulating layer overlies the upper heat conductive base plate and an electrode layer overlies the insulating layer. A hole is formed through the upper heat conductive base plate, the insulating layer and the electrode layer. A lower heat conductive member with a hollow portion of cylindrical shape on a top surface thereof is detachably secured to the upper heat conductive base plate by embedding the hollow portion of cylindrical shape in the hole, thereby disposing a light emitting diode on the top surface of the lower heat conductive member within the hollow portion of cylindrical shape. And a transparent encapsulating unit is adapted to cover the electrode layer and the light emitting diode.

### BRIEF DESCRIPTION OF THE DRAWINGS

The present invention will be described by way of exemplary embodiments, but not limitations, illustrated in the accompanying drawings in which like references denote similar elements, and in which:

FIG. 1 illustrates a perspective exploded view of a LED package pertaining to an exemplary embodiment of the present invention;

FIG. 2A is a perspective view of a LED package pertaining to an exemplary embodiment of the present invention;

FIG. 2B is a perspective view of a LED package pertaining to an exemplary embodiment of the present invention;

FIG. 3 is a graph depicting humidity versus leakage current characteristic for a LED package pertaining to an exemplary embodiment of the present invention; and

FIG. 4 is a graph depicting light intensity versus driving current characteristic for a LED package pertaining to an exemplary embodiment of the present invention.

### DETAILED DESCRIPTION OF THE INVENTION

Various aspects of the system and method of the present invention will be described, and for purposes of explanation, specific configurations and details are set forth in order to provide a thorough understanding of the present invention. However, it will be apparent to one skilled in the art that the present invention may be practiced without these specific details. Furthermore, well known features have been omitted or simplified in order to prevent obscuring the present invention.

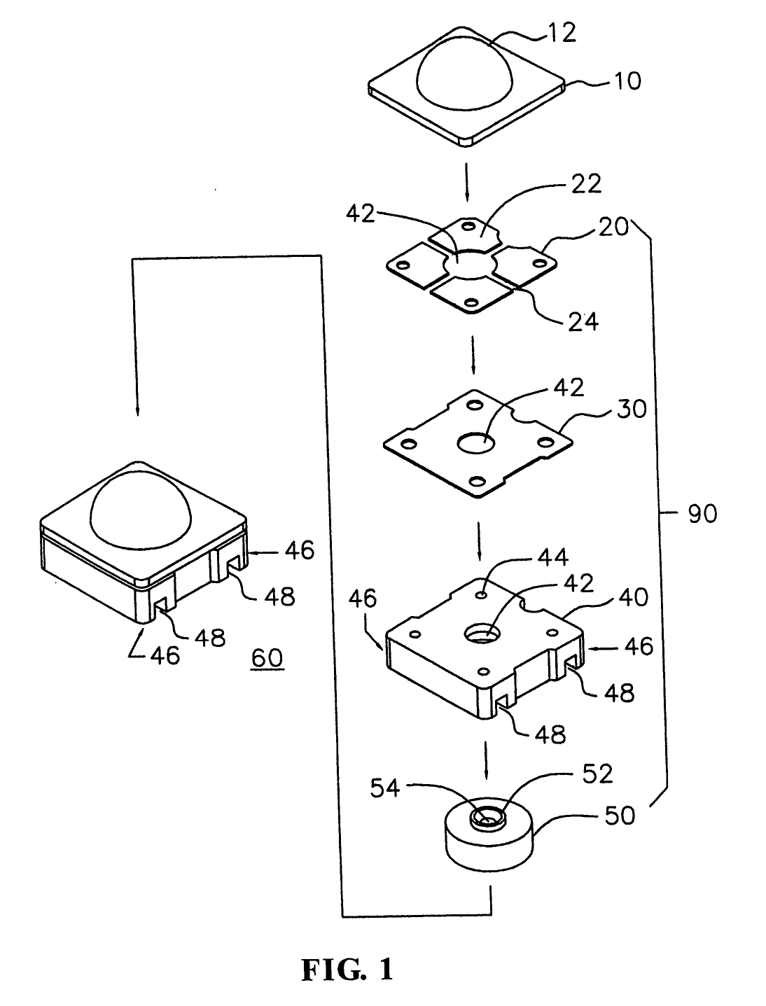

A sectional view of a LED package pertaining to an exemplary embodiment of the invention is shown in FIG. 1. The LED package 60 comprises a heat conductive unit 90 and an encapsulating unit 10 thereon. Typically, the heat conductive unit 90 comprises a composite heat conductive structure such as an upper heat conductive base plate 40 with a hole 42 and a lower heat conductive member 50 with a hollow portion 52 of cylindrical shape on a top surface thereof for good heat dissipation. Preferably, the upper heat conductive base plate 40 is substantially made of ceramic material and the lower heat conductive member 50 is a metal ring such as made of copper, but is not limited thereto.

The lower heat conductive member 50 may be detachably secured to the upper heat conductive base plate 40 by embedding the hollow portion 52 of cylindrical shape in the hole 42, thereby disposing a light emitting diode 54 on the top surface of the lower heat conductive member 50 within the hollow portion 52 of cylindrical shape. Therefore, if a light emitting angle of the LED 54 is abnormal, the lower heat conductive member 50 could be detached from the upper heat conductive base plate 40 for substituting a new one.

In one embodiment, the hollow portion 52 of cylindrical shape preferably comprises a rough outside surface (not shown) or an outside surface coating a thin glue layer for more firmly embedding in the hole 42 of the upper heat conductive base plate 40. The light emitting diode 54 disposed on the lower heat conductive member 50 in the present examples is a gallium nitride semiconductor element.

In an exemplary embodiment of the present invention, optionally, an insulating layer 30 such as oxide or nitride may be disposed overlying the upper heat conductive base plate 40 to prevent moisture permeating. For example, a glass paste could be coated on the upper heat conductive base plate 40 and then cured before formation of an electrode layer 20. Typically, the electrode layer 20 is formed by coating a silver film on the insulating layer and then performing a sintering process.

Furthermore, the electrode layer 20 comprises contact electrodes 22 isolated by trench lines 24 for electrically connecting to the LED 54. The upper heat conductive base plate 40 may comprise a terminal portion 46 located on corners for holding pins which pass through the insulating layer 30 via holes 44 to electrical connect the isolated contact electrodes 22 respectfully.

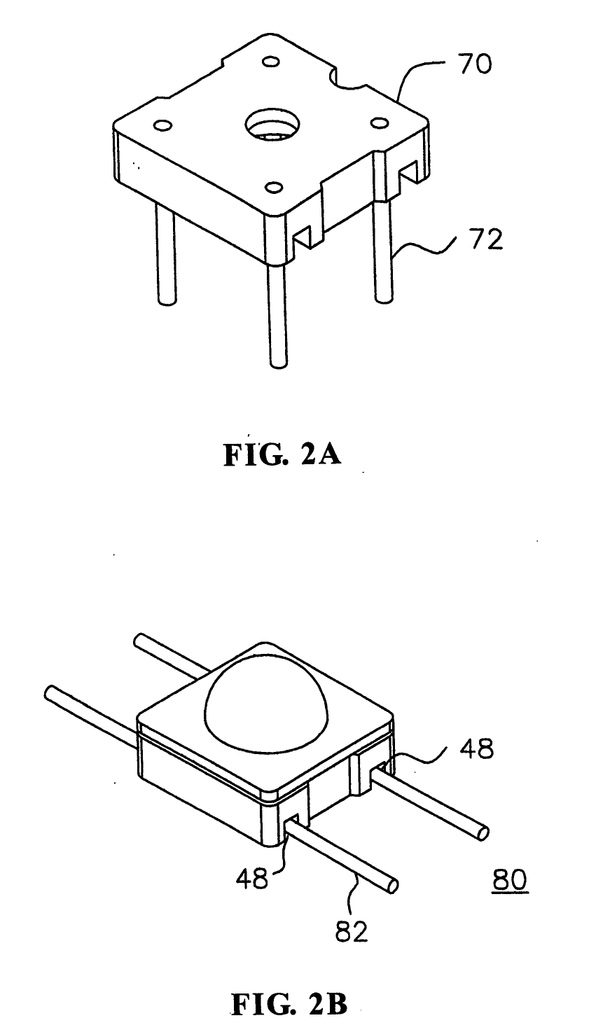

Referring to FIG. 2A, for one example, pins 72 may be substantially perpendicular to a backside surface of the upper heat conductive base plate 40.

Referring to FIG. 2B, for another example, the terminal portion comprises trenches 48 on a backside surface of the upper heat conductive base plate 40 for placing the pins 82 horizontally extended from the trenches 48 to outside of the terminal portion.

In an exemplary embodiment of the present invention, a hole 42, as shown in FIG. 1, may be further formed through the upper heat conductive base plate 40, the insulating layer 30 and the electrode layer 20 such that the hollow portion 52 of cylindrical shape could pass through the hole 42. preferably, the hole 42 of the electrode layer 20 is substantially surrounded by the isolated contact electrodes 22.

A transparent encapsulating unit 10 comprising an encapsulating layer with a cover 12 is adapted to cover the electrode layer 20 and the hollow portion 52 of cylindrical shape for sealing. Typically, the transparent encapsulating layer with the cover 12 may be substantially made of resin, silicone resin, epoxy or glass for protecting the covered LED 30.

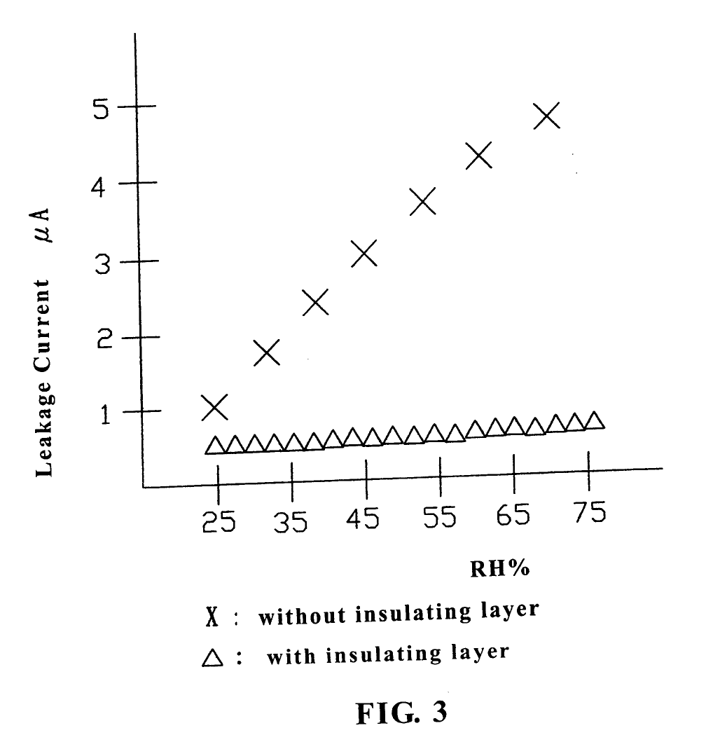

Referring to FIG. 3, as regards moisture permeability, when the insulating layer 30 is formed on the upper heat conductive plate 40 and is exposed to a humidity environment from 25% RH to 85% RH, no abnormal leakage current is observed.

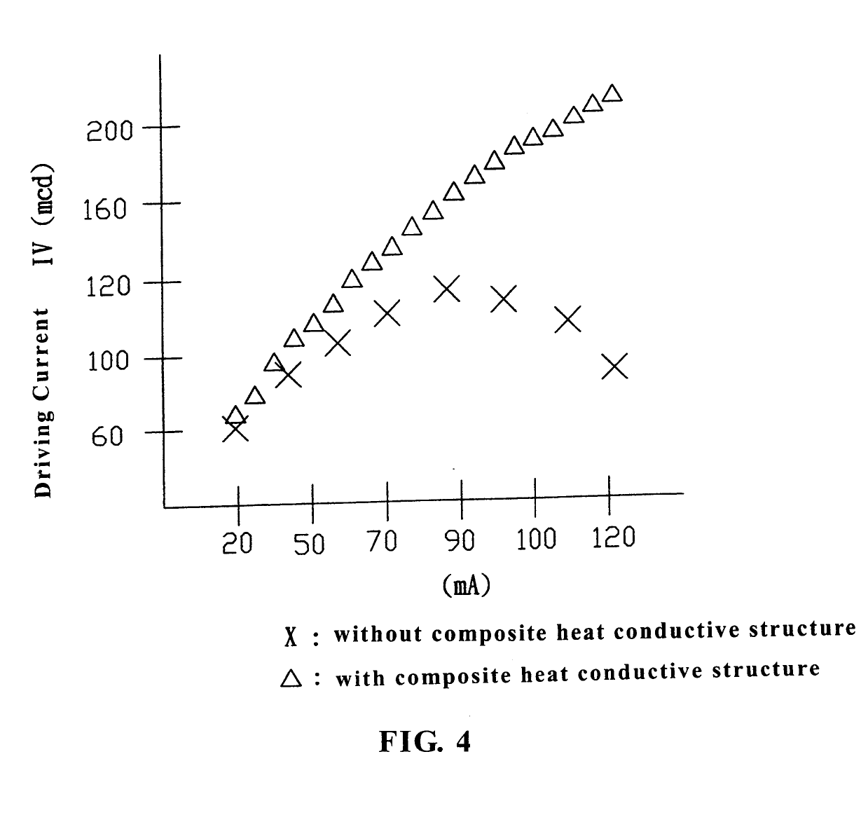

Referring to FIG. 4, as regards heat dissipation, when the heat conductive unit 90 comprising the composite heat conductive structure is formed and driving current of the LED package is increased from 20 mA to 120 mA, the light intensity can continuously increase without attenuation.

While the invention has been described by way of example and in terms of the preferred embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A composite heat conductive structure for a LED package, comprising:
an upper heat conductive base plate with a hole, substantially made of ceramic material;
a lower heat conductive member with a hollow portion of cylindrical shape on a top surface thereof, wherein the lower heat conductive member is detachably secured to the upper heat conductive base plate by embedding the hollow portion of cylindrical shape in the hole, thereby disposing a light emitting diode on the top surface of the lower heat conductive member within the hollow portion of cylindrical shape.

2. The composite heat conductive structure as recited in claim 1, wherein the lower heat conductive member comprises a metal ring.

3. The composite heat conductive structure as recited in claim 1, wherein the hollow portion of cylindrical shape comprises a rough outside surface for more firmly embedding in the hole of the upper heat conductive base plate.

4. A LED package, comprising:
an upper heat conductive base plate, substantially made of ceramic material;
an insulating layer overlying the upper heat conductive base plate;
an electrode layer overlying the insulating layer;
a hole formed through the upper heat conductive base plate, the insulating layer and the electrode layer;
a lower heat conductive member with a hollow portion of cylindrical shape on a top surface thereof, wherein the lower heat conductive member is detachably secured to the upper heat conductive base plate by embedding the hollow portion of cylindrical shape in the hole, thereby disposing a light emitting diode on the top surface of the lower heat conductive member within the hollow portion of cylindrical shape; and
a transparent encapsulating unit covering the electrode layer and the light emitting diode.

5. The LED package as recited in claim 4, wherein the lower heat conductive member comprises a metal ring.

6. The LED package as recited in claim 4, wherein the hollow portion of cylindrical shape comprises a rough outside surface or an outside surface coating a glue layer for more firmly embedding in the hole.

7. The LED package as recited in claim 4, wherein the electrode layer comprises isolated contact electrodes.

8. The LED package as recited in claim 7, wherein the hole is substantially surrounded by the isolated contact electrodes.

9. The LED package as recited in claim 4, wherein the electrode layer is substantially made of silver.

10. The LED package as recited in claim 4, wherein the insulating layer is substantially made of oxide or nitride.

11. The LED package as recited in claim 4, wherein the upper heat conductive base plate comprises a terminal portion for holding pins.

12. The LED package as recited in claim 11, wherein the pins pass through the insulating layer to electrical connect the isolated contact electrodes respectively.

13. The LED package as recited in claim 12, wherein the pins are substantially perpendicular to a backside surface of the upper heat conductive base plate.

14. The LED package as recited in claim 12, wherein the terminal portion comprises trenches on a backside surface thereof for placing the pins horizontally extended from the trenches to outside of the terminal portion.
